(19) United States
(12) Patent Application Publication
(10) Pub. No.: US 2004/0145381 A1
(43) Pub. Date: Jul. 29, 2004

(54) Test fixture for die-level testing of planar lightwave circuits

(76) Inventors: Jun Su, San Jose, CA (US); Yi Ding, Milpitas, CA (US)

Correspondence Address: Charles K. Young, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/040,581

(22) Filed: Dec. 28, 2001

(51) Int. Cl. G01R 31/308

(52) U.S. Cl. 324/753

(57) ABSTRACT

A test fixture is used for testing a hybrid planar lightwave circuit having both electrical and optical inputs and/or outputs. The test fixture comprises a vacuum interface for holding the hybrid planar lightwave circuit in place. The test fixture comprises a mounting area for a circuit board that has a first interface to connect to the hybrid planar lightwave circuit and a second interface to connect to a tester.

### BACKGROUND OF THE INVENTION

1. Field of the Invention

The described invention relates to the field of opto-electronic circuits. In particular, the invention relates to a test fixture for optically and electrically testing an opto-electronic circuit.

2. Description of Related Art

Hybrid planar lightwave circuits (PLCs) are circuits consisting of both electrical and optical functionalities within a plane of a common die. Testing of a hybrid PLC die is challenging because both electrical and optical signals must be interfaced into and out of the hybrid PLC.

A thermo-optic switch (TOS) is an example of a hybrid PLC. The TOS may comprise an optical Mach-Zehnder circuit integrated into a planar silica glass substrate with a thin film metallic heater. It operates electrically by heating one arm of the Mach-Zehnder interferometer, and therefore induces a change in the relative optical path length. At the output coupler of the TOS device, lightwaves interfere either constructively or destructively to switch the optical output.

A conventional probe card has been widely used in the semiconductor industry for electrical testing. The probe card makes physical contact with the test die, but tends to move the test die as the probes are placed. Thus, a conventional probe card approach encounters difficulties with a hybrid PLC since movement of the test die interferes with optical fiber-waveguide alignment.

### BRIEF DESCRIPTION OF THE DRAWINGS

FIG. 1 is a schematic diagram showing a 3-dimensional view of a test fixture for testing a hybrid planar lightwave circuit.

FIG. 2 is a schematic diagram that shows a top view of a test fixture including the internal vacuum cavity.

FIG. 3 is a flowchart that shows an example method of electrically and optically testing a hybrid PLC using the test fixture.

FIG. 4 is a schematic diagram that shows one embodiment of a PCB having a first interface for coupling to the tester.

### DETAILED DESCRIPTION

A test fixture is used for testing a hybrid planar lightwave circuit having both electrical and optical inputs and/or outputs. The test fixture comprises a vacuum interface for holding the hybrid planar lightwave circuit in place. The test fixture comprises a mounting area for a printed circuit board that has a first interface to connect to the hybrid planar lightwave circuit. The printed circuit board also comprises a second interface to connect to a tester.

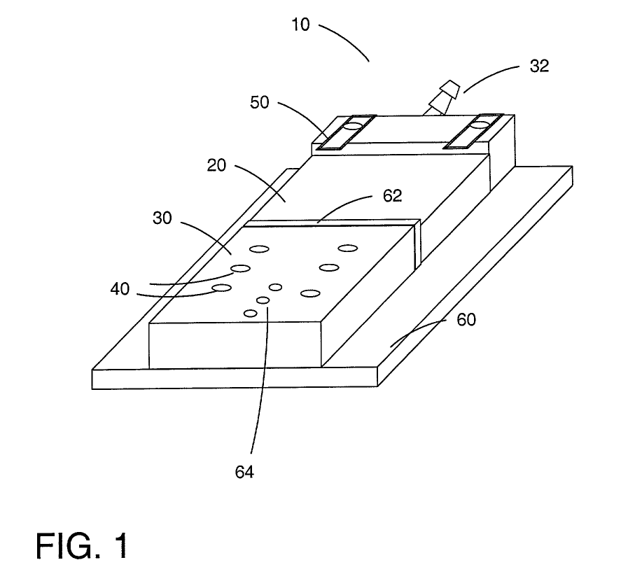

FIG. 1 is a schematic diagram showing a 3-dimensional view of a test fixture 10 for testing a hybrid planar lightwave circuit. The test fixture 10 includes a first mounting area 20 for placing a printed circuit board (PCB), and a second mounting area 30 for placing the hybrid PLC.

The mounting area 30 for the hybrid PLC includes one or more holes 40 leading to an internal vacuum cavity. A vacuum interface 32 is used to attach the test fixture to a vacuum source, which provides suction to the internal vacuum cavity and to the one or more holes 40. When a hybrid PLC is placed in the mounting area 30, the suction through the one or more holes holds the hybrid PLC in place. In one embodiment, the internal vacuum cavity is used to hold the hybrid PLC in place during test. Threaded holes 64 in the test fixture 42 may be used to attach clamps to the test fixture to alternatively or additionally hold the hybrid PLC in place; however, the vacuum interface 32 and holes 40 provide a more uniform force for holding the PLC. Also, clamps may exert stress on the PLC die that may change the optical performance of the die. The PCB may similarly be held by various attachment methods, such as by using locking clamps 50 attached to the test fixture.

A mounting base 60 may be used to affix the test fixture to any flat surface such as optical stages, benches, etc. In one embodiment, a slide-stopper 62, which has different height than the PCB mounting area 20, is used to separate the PCB mounting area 20 from the hybrid PLC mounting area 30.

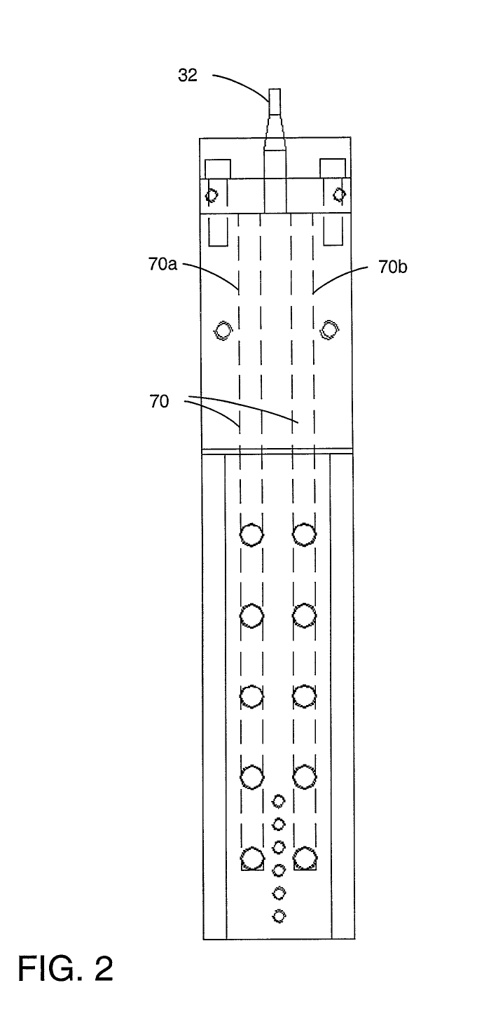

FIG. 2 is a schematic diagram that shows a top view of a test fixture including the internal vacuum cavity 70. In one embodiment, the internal vacuum cavity 70 is split into two channels 70a, 70b. Each of the channels 70a, 70b is coupled to the vacuum interface 32. In one embodiment, the channels are substantially parallel to one another.

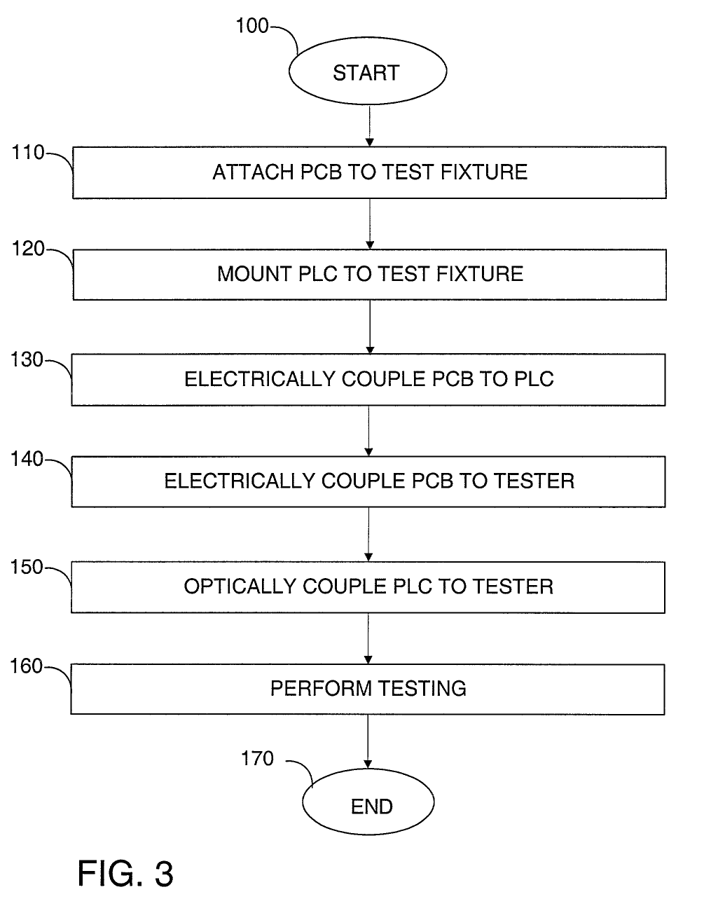

FIG. 3 is a flowchart that shows an example method of electrically and optically testing a hybrid PLC using the test fixture 10. The flowchart starts at block 100, and continues with block 110 at which a PCB is attached to the test fixture. In one example, the PCB is attached to the test fixture via a clamp. However, the PCB could alternatively be attached to the test fixture by other methods such as, but not limited to, bonding, screwing, bolting, etc.

The flowchart continues at block 120, at which the hybrid PLC is mounted to the test fixture. In one embodiment, the PLC is temporarily held in place by suction through the vacuum interface and the holes 40 in the PLC mounting area 30. Other attachment methods, such as using clamps may alternatively or additionally be used.

From block 120, the flowchart continues at block 130, at which the PCB is electrically coupled to the PLC. Soldering, wirebonding, probe pins, or using a conductive epoxy, such as silver epoxy, may electrically couple the PCB and PLC.

The flowchart continues at block 140, at which the PCB is electrically coupled to the tester. In one embodiment, the PCB comprises a first interface for coupling to the tester, and a second interface for coupling to the PCB.

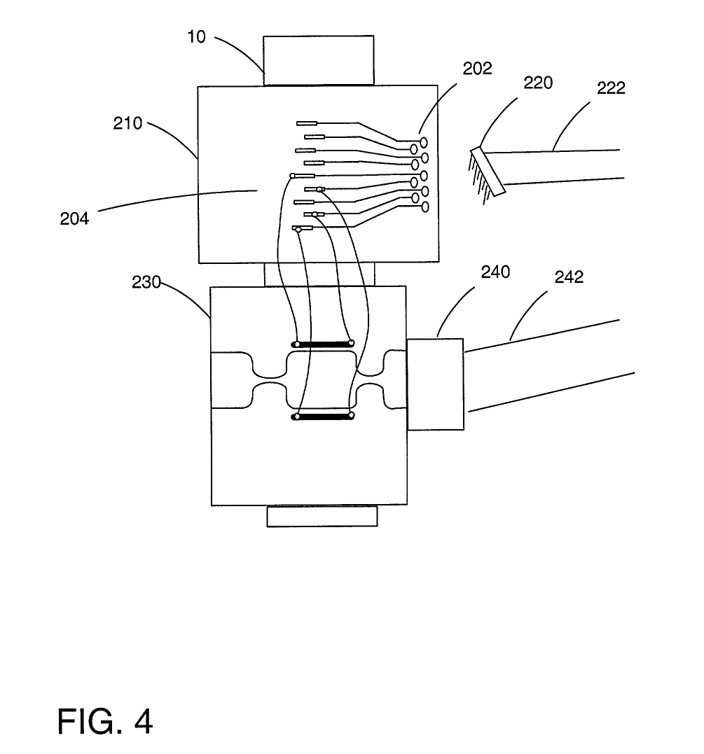

FIG. 4 is a schematic diagram that shows one embodiment of a PCB 210 having a first interface 202 for coupling to the tester. In one embodiment, this may include multiple holes that allow attachment with a multiple pin connector 220. The connector 220 may be coupled to a tester via a ribbon cable 222.

In one embodiment, the PCB 210 may split out the electrical signals from the first interface 202 to a second interface 204 comprising multiple electrical pads. However, the second interface 204 need not be limited to any particular locality on the PCB. For example, the multiple electrical pads may be spread out across the entire PCB 210. The electrical pads of interface 204 may be coupled to various nodes on the hybrid PLC 230 via soldering, wirebonding, probe pins, or conductive epoxy, as previously mentioned. In one embodiment, the electrical pads of interface 204 may be coupled to ends of heating elements of a TOS of the PLC 230.

Returning to the flowchart of FIG. 3, from block 140, the flowchart continues at block 150, at which the PLC is optically coupled to the tester. In one embodiment, this may be achieved by butt coupling the PLC 230 to a V-groove substrate 240 attached to an optical fiber ribbon cable 242, as shown in FIG. 4. However, various other optical coupling methods are possible.

The flowchart continues at block 160 at which the tester may now send electrical and optical signals to the PLC. In one embodiment, test software, for example, LabView, allows the tester to precisely control optical and electrical inputs to the hybrid PLC.

Thus, a test fixture for testing a hybrid PLC having both electrical and optical inputs and/or outputs is disclosed. However, the specific embodiments and methods described herein are merely illustrative. Numerous modifications in form and detail may be made without departing from the scope of the invention as claimed below. The invention is limited only by the scope of the appended claims.

What is claimed is:

1. A method of electrically and optically testing a planar lightwave circuit comprising:
placing the planar lightwave circuit on a test fixture, the test fixture including a printed circuit board;
electrically coupling the printed circuit board to the planar lightwave circuit;
electrically coupling the printed circuit board to a tester;
optically coupling the planar lightwave circuit to the tester; and
performing electrical and optical testing on the planar lightwave circuit.

2. The method of claim 1, further comprising:
holding the planar lightwave circuit in place using a vacuum.

3. The method of claim 1, wherein electrically coupling the printed circuit board to the planar lightwave circuit further comprises:
soldering wires from the printed circuit board to the planar lightwave circuit.

4. The method of claim 3, wherein electrically coupling the printed circuit board to a tester further comprises:
attaching an electrical connector to the printed circuit board, the electrical connector coupled to the tester via a ribbon cable.

5. The method of claim 1, wherein electrically coupling the printed circuit board to the planar lightwave circuit further comprises:
wirebonding wires from the printed circuit board to the planar lightwave circuit.

6. The method of claim 5, wherein electrically coupling the printed circuit board to a tester further comprises:
attaching an electrical connector to the printed circuit board, the electrical connector coupled to the tester via a ribbon cable.

7. The method of claim 1, wherein electrically coupling the printed circuit board to the planar lightwave circuit further comprises:
using a conductive epoxy and wires to electrically couple the printed circuit board to the planar lightwave circuit.

8. A test fixture comprising:
a first area for placing a printed circuit board;
a second area for placing a hybrid PLC, the second area having one or more holes coupled to a vacuum cavity;
a vacuum interface to provide suction in the vacuum cavity.

9. The test fixture of claim 8 further comprising:
an attachment interface for holding the printed circuit board in place.

10. The test fixture of claim 9 further comprising:
a clamp to hold the printed circuit board to the test fixture.

11. The test fixture of claim 8 further comprising:
an attachment interface for holding the hybrid PLC to the test fixture.

12. The test fixture of claim 8 further comprising:
a clamp to hold the hybrid PLC to the test fixture.

13. A test fixture comprising:
a vacuum interface for providing suction to an inner cavity of the test fixture, the inner cavity coupled to an outer surface through one or more holes;
a mounting area for holding a hybrid planar lightwave circuit, wherein the one or more holes are within the mounting area; and
a printed circuit board having a first interface for coupling to a tester connector and a second interface for coupling to the hybrid planar lightwave circuit.

14. The test fixture of claim 13 further comprising:
clamps to hold the printed circuit board to the test fixture.

15. The test fixture of claim 13, wherein the second interface of the printed circuit board comprises wire bond interfaces.

16. The test fixture of claim 13, wherein the second interface of the printed circuit board comprises electrical pads for soldering.

17. The test fixture of claim 13, wherein the inner cavity is split into two or more vacuum channels.

18. The test fixture of claim 17, wherein the two or more vacuum channels are substantially parallel.
